(19) United States
(12) Patent Application Publication
(10) Pub. No.: US 2015/0249149 A1
(43) Pub. Date: Sep. 3, 2015

(54) SEMICONDUCTOR DEVICE AND METHOD OF MANUFACTURING SEMICOUNDUCTOR DEVICE

(71) Applicant: FUJI ELECTRIC CO., LTD., Kawasaki-shi (JP)

(72) Inventor: Hong-fei LU, Matsumoto-city (JP)

(21) Appl. No.: 14/707,366

(22) Filed: May 8, 2015

Related U.S. Application Data
(63) Continuation of application No. PCT/JP2013/050699, filed on Jan. 16, 2013.

(51) Int. Cl. H01L 29/739; H01L 29/06; H01L 21/324; H01L 29/66; H01L 21/265

(52) U.S. Cl. CPC H01L 29/7395; H01L 29/66333; H01L 21/265; H01L 21/324; H01L 29/0619

(57) ABSTRACT

A forward termination structure that surrounds an active region is provided between the active region and a p⁺ isolation region. A reverse termination structure that surrounds the forward termination structure is provided between the forward termination structure and the p⁺ isolation region. The forward termination structure is formed of a plurality of first field limited rings (“FLR”) and a first filed plat (“FP”) conductively connected to the first FLR. The reverse termination structure is formed of a plurality of second FLR and second FP conductively connected to the second FLR. In the reverse termination structure, a second n-type region which is in contact with the p⁺ isolation region and which includes at least one of the second FLRs is provided on a surface layer of the front surface of an n⁻ semiconductor substrate.

### CROSS-REFERENCE TO RELATED APPLICATION

This application is a continuation of International Application No. PCT/JP 2013/050699, filed on Jan. 16, 2013. The disclosure of the PCT application in its entirety, including the drawings, claims, and the specification thereof, are incorporated herein by reference.

### BACKGROUND

1. Field of the Invention

The present invention relates to a semiconductor device and a method of manufacturing the semiconductor device.

2. Related Art

Discrete semiconductors having a high breakdown voltage play an important role in power converters. For example, insulated gate bipolar transistors (IGBT), metal oxide semiconductor field effect transistors (MOSFET), and the like are known as examples of discrete semiconductors.

Since IGBTs have such properties that the ON voltage decreases due to conductivity modulation in a drift region, IGBTs are often used for applications to high-voltage devices. In order to reduce a loss of a power converter, it is one of important issues to reduce a conduction loss and a switching loss of IGBTs. For example, IGBTs have the forward blocking ability but do not have the reverse blocking ability. Due to this, when a bidirectional switch is formed using an IGBT, it is necessary to connect a diode having a high breakdown voltage for blocking a reverse-directional current to the IGBT in series and a conduction loss increases.

A reverse blocking IGBT (RB-IGBT) having a termination structure in which a pn junction between a collector region and a drift region of an IGBT is extended from the back surface of a semiconductor chip to the front surface thereof is known as an example of a low-loss semiconductor device having the reverse blocking ability (for example, see Japanese Patent Application Publication Nos. 2005-093972 and 2006-303410. In the RB-IGBT, a high reverse breakdown voltage is maintained even when a reverse voltage is applied to the pn junction between the collector region and the drift region. Moreover, a bidirectional switch which uses the RB-IGBT can reduce a conduction loss more than a bidirectional switch which uses an IGBT and a diode in combination. The reasons therefor will be described below.

In a reverse blocking semiconductor device in which an IGBT and a diode is connected series, the IGBT and the diode are formed in different semiconductor substrates (semiconductor chips), and a drift region in which a forward voltage is carried is different from a drift region in which a reverse voltage is carried. Due to this, the thickness of a drift region determining the conduction loss of a bidirectional switch is the sum of the thickness of the drift region of the IGBT and the thickness of the drift region of the diode. On the other hand, an RB-IGBT is formed of one semiconductor substrate, and a reverse voltage is also carried in the drift region that carries a forward voltage. Due to this, in the RB-IGBT, the thickness of the drift region that determines the conduction loss of a bidirectional switch is smaller than that of the reverse blocking semiconductor device in which an IGBT and a diode are connected in series, and the loss can be reduced.

Next, the structure of a conventional RB-IGBT will be described. FIG. 12 is a cross-sectional view illustrating a configuration of a conventional RB-IGBT. As illustrated in FIG. 12, a conventional RB-IGBT includes an active region 110 in which a drift current flows and a termination structure 120 for securing a breakdown voltage, which are provided on the front surface side of an n⁻ semiconductor substrate which serves as a n⁻ drift region 101. In the active region 110, an emitter electrode 107 and a MOS gate (an insulated gate including a metal layer, an oxide layer, and a semiconductor layer) structure including a p base region 102, an n⁺ emitter region 103, a gate insulating film 105, and a gate electrode 106 are provided on the front surface side of the n⁻ semiconductor substrate.

An n-type region 112 that suppresses an JFET effect of the active region 110 and functions as a hall barrier layer is provided between the n⁻ drift region 101 and the p base region 102. A p collector region 108 and a collector electrode 109 are provided on the back surface side of the n⁻ semiconductor substrate. The termination structure 120 includes a plurality of floating p-type regions (field limited rings: FLR) 121 that surrounds the active region 110 and a field plate (FP) 122 that is conductively connected to the p-type region 121. Reference numeral 104 is a p⁺ contact region and reference numeral 111 is an interlayer insulating film.

A p⁺ isolation region (silicon penetrating isolation region) 131 that penetrates through the n⁻ drift region 101 from the back surface of the substrate so as to reach the p collector region 108 is provided on the periphery of the n⁻ drift region 101. A field stopper electrode 132 is conductively connected to the p⁺ isolation region 131. As the p⁺ isolation region 131, a trench isolation structure and a structure which includes a p-type region formed so as to be connected to a p collector region by ion implantation on the side wall of a V-shaped groove as well as a structure which has a diffusion and isolation region formed by diffusing impurities as illustrated in FIG. 12 are proposed.

Moreover, as illustrated in FIG. 12, an FLR structure which includes the FLR 121 and the FP 122 provided so as to surround the active region 110 is widely used as the termination structure 120 (for example, see B. J. Baliga, Fundamentals of Power Semiconductor Devices, (US), Springer Science &. Business Media, 2008, p. 137 (also referred to herein as (“Baliga”). Since the FPs 122 are provided over the entire termination structure 120, surface charge accumulation is suppressed and reliability is secured for a long period. FIG. 13 is a cross-sectional view illustrating a termination structure of a conventional IGBT. In FIG. 13, the termination structure of Baliga is applied to a trench gate structure IGBT.

As illustrated in FIG. 13, in an active region 140, an emitter electrode 147 and a MOS gate structure having a trench gate structure including a p base region 142, an n+ emitter region (not illustrated), a trench 144, a gate insulating film 145, and a gate electrode 146 are provided on the front surface side of the n⁻ semiconductor substrate serving as an n⁻ drift region 141. A p⁺-type region 151 is provided on the outer side of the trench 144 on the outermost side so as to be separated from the p base region 142 and an FLR 161a (described later) and be in contact with the gate insulating film 145 provided on the inner wall of the trench 144.

A p base region 152 is provided in the p⁺-type region 151 so as to be in contact with the gate insulating film 145 provided on the inner wall of the trench 144. A conductive region 155 is provided on the front surface of the p⁺-type region 151 with an oxide film 154 interposed. The gate electrode 146 and the conductive region 155 are formed of polysilicon in which n-type impurities are doped. The n buffer region 150, the p collector region 148, and the collector electrode 149 are provided on the back surface side of the n⁻ semiconductor substrate. Reference numerals 143 and 153 are p⁺ contact regions and reference numeral 156 is an interlayer insulating film.

A termination structure 160 having an FLR structure including FLRs 161a to 161e and FPs 162a to 162e is provided around the active region 140. The FLRs 161a to 161e are arranged at a predetermined interval from the inner side of the substrate to the outer side. The FPs 162a to 162e are conductively connected to the FLRs 161a to 161e, respectively. An isolation oxide film 163 is provided on the surface of the n⁻ drift region 141 except a portion where the FLRs 161a to 161e are provided.

Both ends (the ends close to the active region 140 and the ends close to the periphery of the substrate) of each of the FPs 162a to 162e are extended over the isolation oxide film 163. An n⁺ channel stopper region 165 is provided on a surface layer of the front surface of the substrate on the periphery of the n⁻ semiconductor substrate so as to be separated from the FLR 161e on the outermost side of the periphery of the substrate. A channel stopper electrode 166 is conductively connected to the n⁺channel stopper region 165. It is easily conceivable that when the termination structure 160 having such an FLR structure is applied to the RB-IGBT, a reverse termination structure for securing a reverse breakdown voltage is provided to be symmetrical to a forward termination structure for securing a forward breakdown voltage.

Next, a termination structure of a RB-IGBT when the FLR structure is applied to the termination structure 160 will be described. FIG. 14 is a cross-sectional view illustrating an example of a termination structure of a conventional RB-IGBT. As illustrated in FIG. 14, a RB-IGBT includes an active region 110, a forward termination structure 171 that surrounds the active region 110, and a reverse termination structure 176 that surrounds the forward termination structure 171, which are provided on the front surface side of a n⁻ semiconductor substrate which serves as a n⁻ drift region 101. In the active region 110, an MOS gate structure (not illustrated) similarly to FIG. 12, for example, is provided on the front surface side of the n⁻ semiconductor substrate.

A depletion layer that grows from the active region 110 to the periphery of the substrate and an n⁺ channel stopper region 174 having a function of stopping a depletion layer that grows from the periphery of the substrate to the active region 110 are provided between the forward termination structure 171 and the reverse termination structure 176. Reference numeral 175 is a channel stopper electrode. The forward termination structure 171 includes a plurality of first FLRs 172 provided between the active region 110 and the n⁺ channel stopper region 174 at a predetermined interval so as to extend from the inner side of the substrate to the outer side and first FPs 173 conductively connected to the first FLRs 172. The reverse termination structure 176 includes a plurality of second FLRs 177 provided between the n⁺ channel stopper region 174 and the p⁺ isolation region 131 at a predetermined interval so as to extend from the inner side of the substrate to the outer side and second FPs 178 conductively connected to the second FLRs 177.

Next, the operation of the termination structure of the RB-IGBT will be described with reference to FIG. 14. When a forward voltage wherein a collector potential is higher than an emitter potential is applied, similarly to the conventional IGBT, a depletion layer 181 that grows from a pn junction between the p base region 102 and the n⁻ drift region 101 spreads toward the outer side of the substrate due to the forward termination structure 171 which includes the first FLR 172 and the first FP 173. On the other hand, when a reverse voltage wherein a collector potential is lower than an emitter potential is applied, a depletion layer 182 that grows from a pn junction between the p⁺ isolation region 131 and the p collector region 108, and the n⁻ drift region 101 spreads toward the inner side of the substrate due to the reverse termination structure 176 which includes the second FLR 177 and the second FP 178. The forward breakdown voltage and the reverse breakdown voltage of these termination structures are set to be equal to or larger than a breakdown voltage secured by the magnitude corresponding to the thickness of the n⁻ drift region 101.

Moreover, in order to simplify the processes of manufacturing RB-IGBTs, a termination structure having a configuration in which a p channel stopper region of the same conductivity type as the FLR is provided is proposed (for example, see Japanese Patent Application Publication Nos. 2005-252212 and 2011-077202). Moreover, a termination structure having a configuration in which a channel stopper region is not provided between a forward termination structure and a reverse termination structure is proposed (for example, see Japanese Patent Application Publication No. 2005-101254). In Japanese Patent Application Publication No. 2005-101254, a second FLR of a reverse termination structure located closest an active region functions as a channel stopper when a forward voltage is applied, and a first FLR of a forward termination structure located closest to a p⁺ isolation region functions as a channel stopper when a reverse voltage is applied.

However, as illustrated in FIG. 14, the first FLR 172 and the p base region 102 which deplete the n⁻ drift region 101 of the forward termination structure 171 when a forward voltage is applied is selectively formed on a front surface of the substrate. In contrast, the p⁺ isolation region 131 and the p collector region 108 which deplete the n⁻ drift region 101 of the reverse termination structure 176 when a reverse voltage is applied is uniformly formed on the side surface and the rear surface of the substrate, respectively. Due to this, there is a problem in that the n⁻ drift region 101 (in particular, a portion sandwiched between the second FLR 177 and the p collector region 108) of the reverse termination structure 176 is likely to be depleted, and punch-through is more likely to occur in the n⁻ drift region 101 than in the n⁻ drift region 101 of the forward termination structure 171. Thus, a reverse breakdown voltage decreases.

In order to solve this problem, a method of forming a larger number of second FLRs 177 of the reverse termination structure 176 than the number of first FLRs 172 of the forward termination structure 171 to thereby improve the breakdown voltage characteristics (reverse breakdown voltage and charge resistance properties) of the reverse termination structure 176 to the same extent as the reverse-breakdown voltage characteristics of the forward termination structure 171 is known. However, there is a problem in that, when the number of second FLRs 177 of the reverse termination structure 176 is increased, the width (the width in a direction from the inner side of the substrate to the outer side) of the reverse termination structure 176 increases, and the chip size increases.

That is, there is a problem in that, when an increase in the chip size is prevented by forming the same number of second FLRs 177 that constitute the reverse termination structure 176 as the number of first FLRs 172 that constitute the forward termination structure 171, desired breakdown voltage characteristics of the reverse termination structure 176 are not obtained.

### SUMMARY OF THE INVENTION

In order to solve the problems of the conventional techniques, an object of the present invention is to provide a semiconductor device and a method of manufacturing the semiconductor device capable of reducing a reverse termination structure for securing a reverse breakdown voltage. Moreover, in order to solve the problems of the conventional techniques, another object of the present invention is to provide a semiconductor device and a method of manufacturing the semiconductor device capable of improving breakdown voltage characteristics during application of a reverse voltage.

In order to solve the problems and to attain the objects of the present invention, the present invention provides a semiconductor device having the following features. A second conductivity-type isolation region is provided on a side surface of a first conductivity-type semiconductor substrate so as to extend from a front surface of the first conductivity-type semiconductor substrate to reach a back surface of the first conductivity-type semiconductor substrate. A first edge termination region provided between an active region and the second conductivity-type isolation region so as to surround the active region. A second edge termination region provided between the first edge termination region and the second conductivity-type isolation region so as to surround the first edge termination region. A plurality of second conductivity-type semiconductor regions selectively provided in a surface layer of the front surface of the first conductivity-type semiconductor substrate in the first and second edge termination regions. A conductive film being in contact with the second conductivity-type semiconductor region. A first conductivity-type semiconductor region exhibiting lower resistivity than the first conductivity-type semiconductor substrate is provided in the surface layer of the front surface of the first conductivity-type semiconductor substrate in the second edge termination region. The first conductivity-type semiconductor region is in contact with at least one second conductivity-type semiconductor region.

In the semiconductor device of the present invention, the first conductivity-type semiconductor region may include at least one of the second conductivity-type semiconductor regions.

The semiconductor device of the present invention may further include a channel stopper region provided in the surface layer of the front surface of the first conductivity-type semiconductor substrate at a boundary between the first edge termination region and the second edge termination region so as to stop a depletion layer which grows from the active region during application of a forward voltage. The semiconductor device of the present invention may further include a channel stopper region provided in the surface layer of the front surface of the first conductivity-type semiconductor substrate at a boundary between the first edge termination region and the second edge termination region so as to stop a depletion layer which grows from the second conductivity-type isolation region during application of a reverse voltage. The semiconductor device of the present invention may further include a first metal film being in contact with the channel stopper region.

In the semiconductor device of the present invention, a dose of the first conductivity-type semiconductor region may be 0.1×10/cm² to 1.6×10¹²/cm².

The semiconductor device of the present invention may further include an oxide film provided on a front surface of a portion of the first conductivity-type semiconductor substrate, with the portion being sandwiched between adjacent second conductivity-type semiconductor regions. Moreover, an end of the conductive film may be extended over the oxide film.

In the semiconductor device of the present invention, in the first edge termination region, an extension length of an inner-side end of the conductive film extended to the oxide film may be larger than an extension length of an outer-side end of the conductive film extended to the oxide film.

In the semiconductor device of the present invention, in the second edge termination region, an extension length of an inner-side end of the conductive film extended to the oxide film may be smaller than an extension length of an outer-side end of the conductive film extended to the oxide film.

The semiconductor device according to the present invention may further include a second metal film that is in contact with the conductive film closest to the second edge termination region among the plurality of conductive films of the first edge termination region. The semiconductor device of the present invention may further include an interlayer insulating film that covers the conductive film. Moreover, an end of the second metal film may be extended over the interlayer insulating film. An outer-side end of the second metal film may be extended toward the outer side longer than an outer-side end of the conductive film to which the second metal film is connected.

The semiconductor device according to the present invention may further include a third metal film that is in contact with the conductive film closest to the first edge termination region among the plurality of conductive films of the second edge termination region. Moreover, an end of the third metal film may be extended over the interlayer insulating film. An inner-side end of the third metal film may be extended toward the inner side longer than an inner-side end of the conductive film to which the third metal film is connected.

In order to solve the problems and to attain the objects of the present invention, the present invention provides a method of manufacturing a semiconductor device including a second conductivity-type isolation region provided on a side surface of a first conductivity-type semiconductor substrate; a first edge termination region provided between an active region and the second conductivity-type isolation region so as to surround the active region; and a second edge termination region provided between the first edge termination region and the second conductivity-type isolation region so as to surround the first edge termination region. The method has the following features. First, a first ion implantation step of selectively implanting first conductivity-type impurities to a front surface of the first conductivity-type semiconductor substrate in the second edge termination region is performed. Subsequently, a second ion implantation step of selectively implanting second conductivity-type impurities to a front surface on a periphery of the first conductivity-type semiconductor substrate is performed after the first ion implantation step is performed. After that, a first diffusion step of diffusing the first conductivity-type impurities by heat treatment to form a first conductivity-type semiconductor region having lower resistivity than the first conductivity-type semiconductor substrate on a surface layer of the front surface of the first conductivity-type semiconductor substrate is performed. After that, a second diffusion step of diffusing the second conductivity-type impurities by heat treatment to form the second conductivity-type isolation region on the periphery of the first conductivity-type semiconductor substrate so as to extend from the front surface of the first conductivity-type semiconductor substrate to reach a back surface of the first conductivity-type semiconductor substrate is performed. After that, a forming step of forming a plurality of second conductivity-type semiconductor regions, at least a portion of which is in contact with the first conductivity-type semiconductor region on the surface layer of the front surface of the first conductivity-type semiconductor substrate in the second edge termination region is performed after the second diffusion step is performed.

In the method of manufacturing the semiconductor device according to the present invention, the first diffusion step may be performed before the second ion implantation step is performed, or may be performed simultaneously with the second diffusion step after the second ion implantation step is performed.

According to the inventions, since the n-type region (the first conductivity-type semiconductor region) is provided on the front surface side of the substrate of the reverse termination structure (the second edge termination region), the dose of the n⁻ drift region of the reverse termination structure is compensated. Due to this, a growth width of a depletion layer which grows toward the inner side of the substrate within the reverse termination structure during application of the maximum reverse voltage can be set to be identical to a growth width of a depletion layer which grows toward the outer side of the substrate within the forward termination structure during application of the maximum forward voltage. Thus, it is possible to reduce the number of field limited rings of the reverse termination structure as compared to the conventional structure.

According to the semiconductor device and the method of manufacturing the semiconductor device according to the present invention, it is possible to improve breakdown voltage characteristics during application of a reverse voltage. According to the semiconductor device and the method of manufacturing the semiconductor device according to the present invention, it is possible to reduce a reverse termination structure for securing a reverse breakdown voltage.

### BRIEF DESCRIPTION OF THE DRAWINGS

FIG. 1 is a cross-sectional view illustrating a configuration of a semiconductor device according to a first embodiment;

FIG. 2 is a cross-sectional view illustrating the state, during manufacturing, of the semiconductor device according to the first embodiment;

FIG. 3 is a cross-sectional view illustrating the state, during manufacturing, of the semiconductor device according to the first embodiment;

FIG. 4 is a cross-sectional view illustrating the state, during manufacturing, of the semiconductor device according to the first embodiment;

FIG. 5 is a cross-sectional view illustrating the state, during manufacturing, of the semiconductor device according to the first embodiment;

FIG. 6 is a cross-sectional view illustrating a configuration of a semiconductor device according to a second embodiment;

FIG. 7 is a cross-sectional view illustrating another example of a configuration of the semiconductor device according to the second embodiment;

FIG. 8 is a cross-sectional view illustrating the state of a depletion layer, during application of a maximum voltage, of a semiconductor device according to the present invention;

FIG. 9 is a characteristic diagram illustrating a impurity-concentration profile along line A-A′ of FIG. 1;

FIG. 10 is a characteristic diagram illustrating a relation between a reverse breakdown voltage and a surface charge of a reverse termination structure in the semiconductor device according to first and second examples;

FIG. 11 is a characteristic diagram illustrating a relation between a reverse breakdown voltage and a dose in a second n-type region of a reverse termination structure in the semiconductor device according to the second example;

FIG. 12 is a cross-sectional view illustrating a configuration of a conventional RB-IGBT;

FIG. 13 is a cross-sectional view illustrating a termination structure of a conventional IGBT; and

FIG. 14 is a cross-sectional view illustrating an example of a termination structure of a conventional RB-IGBT.

### DETAILED DESCRIPTION

Hereinafter, preferred embodiments of a semiconductor device and a method of manufacturing the semiconductor device according to the present invention will be described in detail with reference to the accompanying drawings. In the present specification and the accompanying drawings, a prefix n or p added to a layer or a region means that electrons or holes are majority carriers in the layer or region. Moreover, a suffix + or − added to the prefix n or p means that a layer or a region with the suffix + or − has a higher or lower impurity concentration than a layer or a region without the suffix. In the following description of embodiments and the accompanying drawings, the same configurations are denoted by the same numerals and redundant description thereof will not be provided.

### First Embodiment

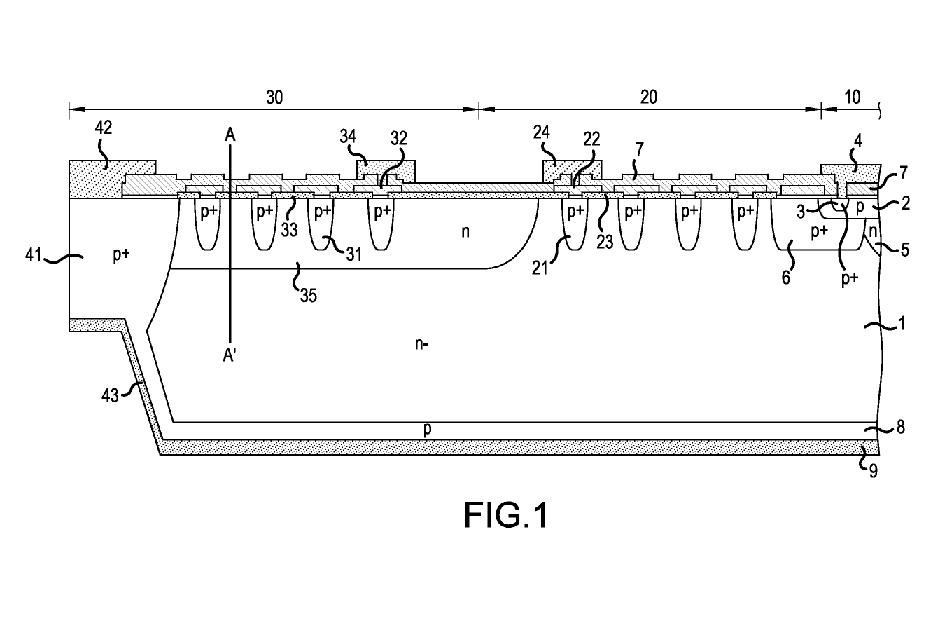

A semiconductor device according to a first embodiment will be described. FIG. 1 is a cross-sectional view illustrating a configuration of a semiconductor device according to the first embodiment. As illustrated in FIG. 1, the semiconductor device according to the first embodiment includes an active region 10 in which a drift current flows, a forward termination structure (first edge termination region) 20 for securing a forward breakdown voltage, and a reverse termination structure (second edge termination region) 30 for securing a reverse breakdown voltage, which are provided on the front surface side of a n⁻ semiconductor substrate (semiconductor chip) serving as an n⁻ drift region 1. The forward termination structure 20 surrounds the active region 10. The reverse termination structure 30 surrounds the forward termination structure 20.

In the active region 10, a planar gate-type MOS gate structure (not illustrated) including a p base region 2, a p⁺ contact region 3, a n⁺ emitter region, a gate insulating film, and a gate electrode and an emitter electrode 4 are provided on the front surface side of the n⁻ semiconductor substrate. A first n-type region 5 and a p⁺-type region 6 are selectively provided between the n⁻ drift region 1 and the p base region 2. The first n-type region 5 covers a region extending from the inner-side end of the p base region 2 to a portion of the p base region 2 on the back surface side of the substrate. The first n-type region 5 suppresses a JFET effect of the active region 10 and functions as a hall barrier layer.

The p⁺-type region 6 covers a region extending from an outer-side end of the p base region 2 to a portion of the p base region 2 on the back surface side of the substrate. The p⁺-type region 6 is separated from a first FLR 21 described later. A p⁺ isolation region 41 having a predetermined depth from the front surface of the substrate is selectively provided on the periphery of the n⁻ semiconductor substrate. The p⁺ isolation region 41 is separated from a second FLR 31 described later. The field stopper electrode 42 is conductively connected to the p⁺ isolation region 41 through a contact hole formed in an interlayer insulating film 7. A V-shaped groove 43 that reaches the p⁺ isolation region 41 from the back surface of the substrate is formed on the periphery of the back surface of the n⁻ semiconductor substrate. Due to the V-shaped groove 43, the thickness on the periphery of the n⁻ semiconductor substrate is smaller than that on the active region 10.

A p collector region 8 is provided on the entire back surface (including the inner wall of the V-shaped groove 43) of the n⁻ semiconductor substrate. The p collector region 8 is connected to the p⁺ isolation region 41 exposed to the inner wall of the V-shaped groove 43, and the pn junction between the p collector region 8 and the n⁻ drift region 1 extends from the back surface of the n⁻ semiconductor substrate to the front surface. That is, a silicon penetrating isolation layer structure to which the p collector region 8 and the p⁺ isolation region 41 are connected so as to surround the reverse termination structure 30 is provided on the periphery of the n⁻ semiconductor substrate. The collector electrode 9 is conductively connected to the p collector region 8.

The forward termination structure 20 includes a plurality of floating p⁺-type regions (hereinafter referred to as first FLRs or second conductivity-type semiconductor regions) 21 provided on the front surface side of the n⁻ semiconductor substrate at a predetermined interval so as to extend from the inner side of the substrate to the outer side and field plates (hereinafter first FPs or conductive films) 22 formed from polysilicon conductively connected to the first FLRs 21. Although a thin oxide film which is formed when a gate oxide film is formed is present at the interface between the first FLR 21 and the first FP 22, the thin oxide film is removed from a chip corner portion so that the first FP 22 and the first FLR 21 are electrically connected. A isolation oxide film 23 is provided on the surface of the n⁻ drift region 1 except a portion where the first FLRs 21 are provided. Both ends (the ends close to the active region 10 and the ends close to the periphery of the substrate) of each of the first FPs 22 are extended over the isolation oxide film 23.

That is, the interval between the adjacent first FPs 22 near the interface between the first FLRs 21 and the first FPs 22 is larger than the interval between the adjacent first FPs 22 in the portion of the first FPs 22 extended over the isolation oxide film 23. Due to this, it is possible to narrow the region which is not covered with the first FPs 22 to block electric charges from the outside and to decrease the width of the opening of the isolation oxide film 23 serving as a contact portion between the first FLR 21 and the first FP 22 to improve the element reliability. The extension length of the end of the first FP 22 close to the active region 10 (the substrate) extended to the isolation oxide film 23 is larger than the extension length of the end of the first FP 22 close to the periphery (the outer side) of the substrate extended to the isolation oxide film 23. Due to this, it is possible to suppress the growth of a depletion layer that grows from the pn junction between the p base region 2 and the n⁻ drift region 1.

A field plate (hereinafter referred to as a first metal FP or a second metal film) 24 formed from a metal film is conductively connected to the first FP 22 located closest to the periphery of the substrate through a contact hole formed in the interlayer insulating film 7. The end of the first metal FP 24 is extended over the interlayer insulating film 7. The end of the first metal FP 24 close to the periphery of the substrate is extended toward the periphery of the substrate longer than the end close to the periphery of the substrate, of the FP 22 to which the first metal FP 24 is connected. The first metal FP 24 has a function of suppressing the depletion layer growing from the pn junction between the p⁺ isolation region 41 and the p collector region 8, and the n⁻ drift region 1 from spreading from the first metal FP 24 toward the active region 10.

The reverse termination structure 30 includes a plurality of floating p⁺-type regions (hereinafter second FLRs or second conductivity-type semiconductor regions) 31 provided on the front surface side of the n⁻ semiconductor substrate at a predetermined interval from the inner side of the substrate to the outer side and field plates 32 (hereinafter second FPs or conductive films) formed from polysilicon, conductively connected to the second FLRs 31. Although a thin oxide film which is formed when a gate oxide film is formed is present at the interface between the second FLR 31 and the second FP 32, the thin oxide film is removed from the chip corner portion so that the second FP 32 and the second FLR 31 are electrically connected. The number of second FLRs 31 is the same as the number of first FLRs 21, for example. A isolation oxide film 33 is provided on the surface of the n⁻ drift region 1 except a portion where the second FLRs 31 are provided. Both ends (the ends close to the active region 10 and the ends close to the periphery of the substrate) of each of the second FPs 32 are extended over the isolation oxide film 33.

That is, the interval between the adjacent second FPs 32 near the interface between the second FLRs 31 and the second FPs 32 is larger than the interval between the adjacent second FPs 32 in the portion of the second FPs 32 extended over the isolation oxide film 33. Due to this, it is possible to narrow the region which is not covered with the second FPs 32 to block electric field from the outside and to decrease the width of the opening of the isolation oxide film 33 serving as a contact portion between the second FLR 31 and the second FP 32 to improve the element reliability. The extension length of the end of the second FP 32 close to the active region 10 extended to the isolation oxide film 33 is smaller than the extension length of the end of the second FP 32 close to the periphery of the substrate extended to the isolation oxide film 33. Due to this, it is possible to suppress the growth of the depletion layer growing from the pn junction between the p⁺ isolation region 41 and the p collector region 8, and the n⁻ drift region 1.

A field plate (hereinafter referred to as a second metal FP or a third metal film) 34 formed from a metal film is conductively connected to the second FP 32 closest to the active region 10 through a contact hole formed in the interlayer insulating film 7. The end of the second metal FP 34 is extended over the interlayer insulating film 7. The end of the second metal FP 34 close to the active region 10 is extended toward the active region 10 longer than the end of the second FP 32 close to the active region 10, to which the second metal FP 34 is connected. The second metal FP 34 has a function of suppressing a depletion layer growing from the pn junction between the p base region 2 and the n⁻ drift region 1 from spreading from the second metal FP 34 to the periphery of the substrate.

Moreover, the reverse termination structure 30 has a double resurf structure due to the p collector region 8 and the second FLRs 31 of the reverse termination structure 30. The double resurf structure means a structure in which a depletion layer spreads from the interfaces of the second FLR 31 on the front surface side of the substrate at the end of the n⁻ drift region 1 and the p collector region 8 on the back surface side of the substrate. In the reverse termination structure 30, a second n-type region (first conductivity-type semiconductor region) 35 that includes one or more second FLRs 31 is provided on the surface layer on the front surface of the n⁻ semiconductor substrate so as to be in contact with the p⁺ isolation region 41.

The second n-type region 35 may be provided so as to extend from the p⁺ isolation region 41 to the vicinity of the boundary between the reverse termination structure 30 and the forward termination structure 20. The second n-type region 35 is provided so as to be separated from the first FLRs 21. The depth of the second n-type region 35 may be the same as the depth of the second FLRs 31 and may be smaller than the depth of the second FLRs 31. That is, the second n-type region 35 may be in contact with the n⁻ drift region 1 and the second FLRs 31 included therein. A dose of the second n-type region 35 may be 0.1×10¹²/cm² to 1.6×10¹²/cm², for example. The sum of the dose of the n⁻ drift region 1 and the dose of the second n-type region 35 may be 2×10¹²/cm² to 3×10¹²/cm², for example.

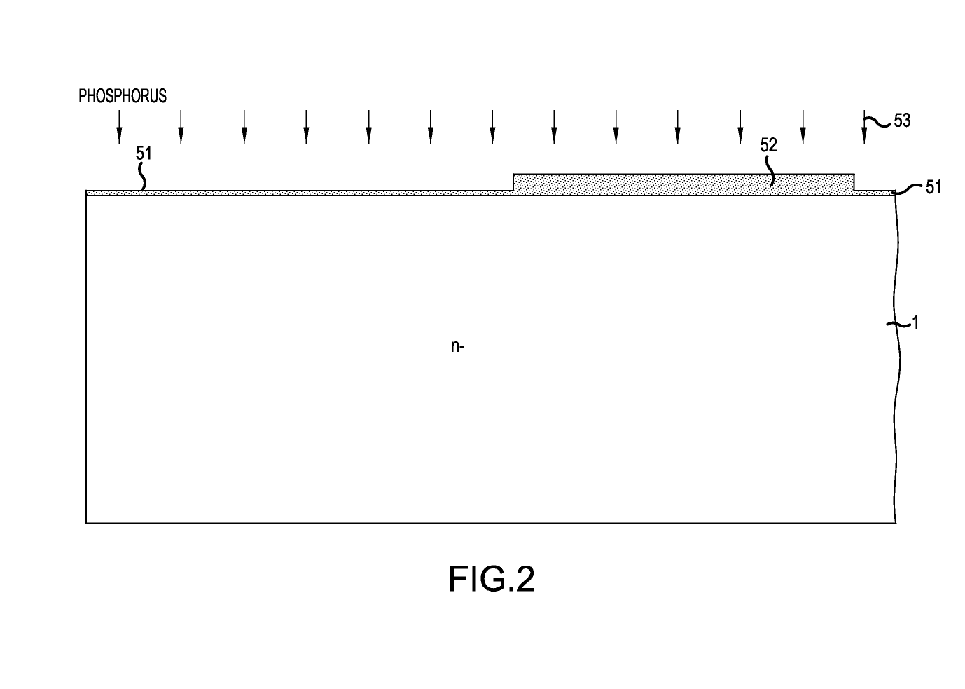

Next, a method of manufacturing the semiconductor device according to the first embodiment will be described. FIGS. 2 to 5 are cross-sectional views illustrating the state, during manufacturing, of the semiconductor device according to the first embodiment. First, as illustrated in FIG. 2, a screen oxide film 51 is formed, by thermal oxidation or deposition, on an n⁻-type semiconductor wafer (hereinafter referred to as a FZ wafer 1) serving as the n⁻ drift region 1 sliced from an ingot according to a floating zone (FZ) method. Subsequently, a resist is applied to the screen oxide film 51 and a resist mask 52 in which a portion corresponding to the forming region of the first and second n-type regions 5 and 35 is open is formed according to photolithography.

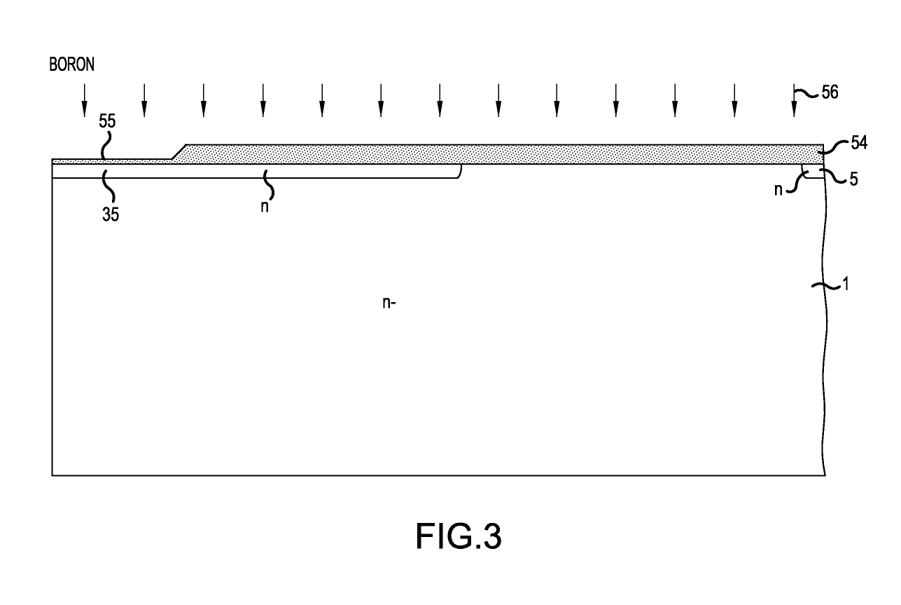

Subsequently, first ion implantation 53 is performed so that n-type impurities such as phosphorus (P), for example, are implanted on the front surface of the FZ wafer 1 exposed to the opening of the resist mask 52 using the resist mask 52 as a mask from the upper surface of the screen oxide film 51. In this way, n-type impurity regions serving as the first and second n-type regions 5 and 35 are formed on the surface layer of the front surface of the FZ wafer 1. In FIG. 3, the n-type impurity regions serving as the first and second n-type regions 5 and 35 are indicated by reference numerals 5 and 35. When the first n-type region 5 is not formed, an opening may be formed in the resist mask 52 so that only the portion (the opening on the left side of the resist mask 52) corresponding to the forming region of the second n-type region 35 is exposed. The dose of the first ion implantation 53 may be 0.1×10¹²/cm² to 1.6×10¹²/cm², for example. This is because the dose of the second n-type region 35 after a RB-IGBT is manufactured can be set to a desired dose.

Acceleration energy of the first ion implantation 53 and the thickness of the screen oxide film 51 may be adjusted according to the dose of the first ion implantation 53. Specifically, the lower the dose of the first ion implantation 53, the smaller the thickness of the screen oxide film 51 and the smaller the acceleration energy of the first ion implantation 53 are set. For example, when the dose of the first ion implantation 53 is 0.4×10¹²/cm², the thickness of the screen oxide film 51 may be set to 30 nm and the acceleration energy of the first ion implantation 53 may be set to 150 KeV. Detailed conditions of the dose of the first ion implantation 53 for forming the second n-type region 35 will be described later.

Moreover, the first ion implantation 53 may be performed using general ion implantation techniques performed in microelectromechanical systems (MEMS), for example, or may be performed using ion implantation techniques reported in Takae Sukegawa, “2007 Semiconductor Technology Outlook” (Electronic Journal Supplement), May 22, 2007, vol. 4, chapter 5, section 1, p. 307 to 310, and Robert. Doering et al., “Handbook of Semiconductor Manufacturing Technology, Second Edition” (CRC Press), Jul. 9, 2007, US, p. 7-32 to 7-34.

Subsequently, as illustrated in FIG. 3, the resist mask 52 is removed. Subsequently, a first thermal diffusion treatment (drive-in) is performed for 10 minutes at a temperature of 700° C. or higher in a nitrogen (N²) atmosphere, for example, to thermally diffuse the n-type impurity regions serving as the first and second n-type regions 5 and 35 to form the first and second n-type regions 5 and 35. Subsequently, the FZ wafer 1 is exposed to an oxidizing atmosphere to form an oxide film 54 having a thickness of 0.8 μm on the front surface of the FZ wafer 1. Subsequently, wet-etching is performed using the resist mask (not illustrated) formed on the oxide film 54 according to photolithography as a mask to remove the oxide film 54 in the portion corresponding to the forming region of the p⁺ isolation region 41. Moreover, the resist mask used for etching the oxide film 54 is removed. Subsequently, thermal oxidation and deposition is performed to form a screen oxide film 55 having a thickness of 30 nm in the opening of the oxide film 54.

Subsequently, second ion implantation 56 is performed to implant p-type impurities such as boron (B), for example, to the front surface of the FZ wafer 1 exposed to the opening of the oxide film 54 using as a mask the residual portion of the oxide film 54 from the upper surface of the screen oxide film 55. In this way, a p-type impurity region serving as the p⁺ isolation region 41 is formed on the surface layer of the front surface of the FZ wafer 1. The dose and the acceleration energy of the second ion implantation 56 may be 1.0×10¹⁵/cm² and 45 KeV, respectively, for example. Subsequently, a second thermal diffusion treatment is performed for 150 hours at a temperature of 1300° C. in an inert gas atmosphere containing oxygen (O²) to thermally diffuse the p-type impurity region serving as the p⁺ isolation region 41 to form the p⁺ isolation region 41.

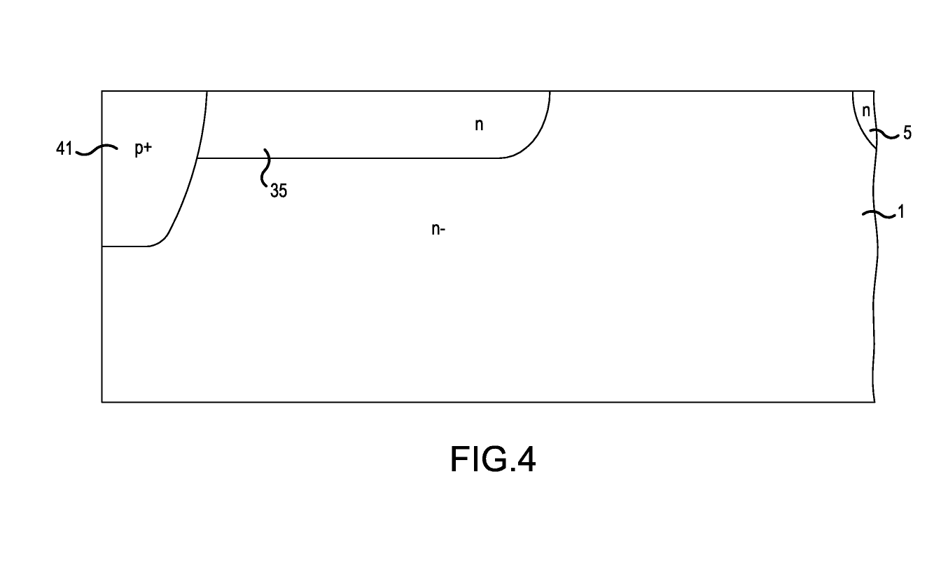

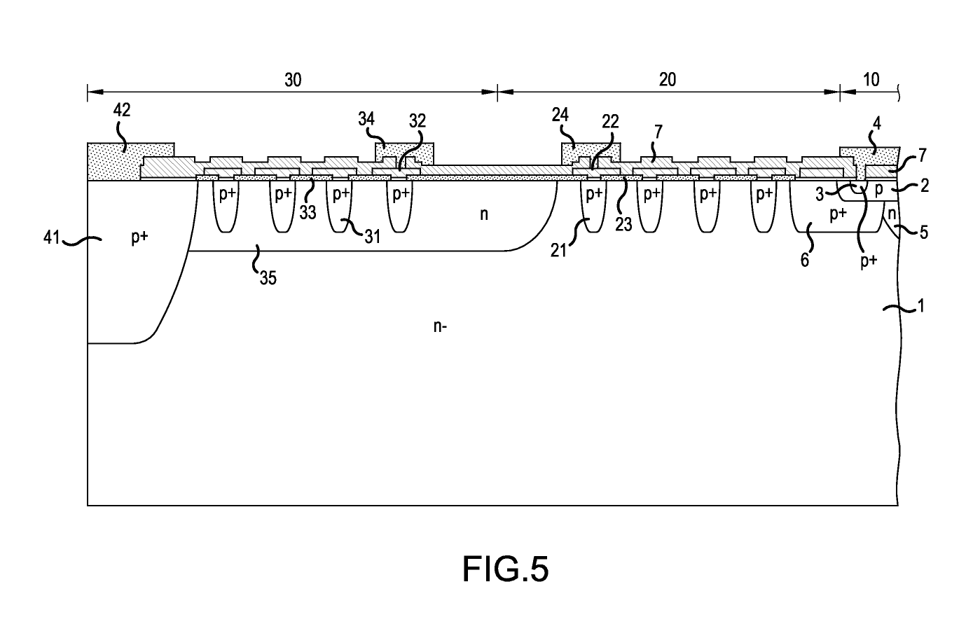

Subsequently, as illustrated in FIG. 4, the oxide film 54 and the screen oxide film 55 are removed. Subsequently, as illustrated in FIG. 5, a front surface device structure is formed on the front surface side of the FZ wafer 1 according to a general method. Examples of the front surface device structure include a MOS gate structure (not illustrated) of the active region 10, the first FLR 21, the first FP 22, the isolation oxide film 23, and the first metal FP 24 of the forward termination structure 20, and the second FLR 31, the second FP 32, the isolation oxide film 33, and the second metal FP 34 of the reverse termination structure 30. Subsequently, a carrier life time is adjusted by electron beam radiation or the like, for example. Subsequently, the back surface of the FZ wafer 1 is ground to decrease the thickness of the FZ wafer 1 to a desired thickness. Subsequently, the front surface device structure formed on the front surface side of the FZ wafer 1 is protected by a protection film.

Subsequently, silicon anisotropic etching is performed using an alkaline solution such as TMAH, for example, using a resist mask (not illustrated) formed on the back surface of the FZ wafer 1 as a mask on the basis of photo lithography to form the V-shaped groove 43 that reaches the p⁺ isolation region 41. Subsequently, the resist mask used for forming the V-shaped groove 43 is removed. Subsequently, third ion implantation is performed to implant p-type impurities such as boron, for example, to the entire back surface (including the inner wall of the V-shaped groove 43) of the FZ wafer 1 to form the p collector region 8 on the entire back surface of the FZ wafer 1. Subsequently, a metal film serving as the collector electrode 9 is deposited onto the p collector region 8 according to a sputtering method, for example. After that, the FZ wafer 1 is diced to form chips, whereby the RB-IGBT illustrated in FIG. 1 is manufactured.

In the method of manufacturing the semiconductor device according to the first embodiment, the first thermal diffusion treatment of thermally diffusing the n-type impurity region serving as the first and second n-type regions 5 and 35 is performed at a different point in time from the second thermal diffusion treatment of thermally diffusing the p-type impurity region serving as the p⁺ isolation region 41. However, the first thermal diffusion treatment and the second thermal diffusion treatment may be performed simultaneously after the second ion implantation 56 for forming the p-type impurity region serving as the p⁺ isolation region 41 is performed. Moreover, the first thermal diffusion treatment may be performed twice after the first ion implantation 53 for forming the n-type impurity region serving as the first and second n-type regions 5 and 35 is performed and after the second ion implantation 56 for forming the p-type impurity region serving as the p⁺ isolation region 41 is performed.

Moreover, a case of producing (manufacturing) an RB-IGBT having a configuration in which the V-shaped groove 43 is formed on the back surface of the substrate so that the thickness on the periphery of the substrate is smaller than the thickness on the active region 10 has been described. However, the present invention is not limited to this, and the present invention can be applied to a case of producing an RB-IGBT having a configuration in which the thickness of the n⁻ semiconductor substrate on the active region 10 is the same as that on the periphery. In this case, rather than performing the step of forming the V-shaped groove 43, the p⁺ isolation region 41 may be thermally diffused so as to extend from the front surface of the FZ wafer 1 to the back surface in the step of thermally diffusing the p⁺ isolation region 41 formed in the second ion implantation 56.

(Impurity-Concentration Profile of Reverse Termination Structure)

Next, an n-type impurity-concentration profile of the reverse termination structure 30 will be described. In order to completely deplete the n⁻ drift region 1 of the reverse termination structure 30 by a depletion layer extending from the pn junction between the p collector region 8 and the n⁻ drift region 1 and the pn junction between the n⁻ drift region 1 and the second FLR 31 of the reverse termination structure 30, a theoretically ideal dose of the n⁻ drift region 1 of the resurf structure is approximately 2.0×10¹²/cm². Moreover, since a depletion layer extends from the pn junction between the p⁺ isolation region 41 and the n⁻ drift region 1 toward the inner side of the substrate, the n⁻ drift region 1 may have a high dose which may be increased up to approximately 1.0×10¹²/cm². That is, an ideal dose of the n⁻ drift region 1 is approximately 2.0×10¹²/cm² to 3.0×10¹²/cm².

A thickness and an average impurity concentration of the n⁻ drift region of a conventional RB-IGBT having a breakdown voltage of 1200 V are approximately 185 μm and 8.25×10¹³/cm³, respectively, for example. Moreover, a thickness and an average impurity concentration of the n⁻ drift region of a conventional RB-IGBT having a breakdown voltage of 1700 V are approximately 275 μm and 5.56×10¹³/cm³, respectively, for example. That is, a dose of the n⁻ drift region of the conventional RB-IGBT is approximately 1.4×10¹²/cm² to 1.6×10¹²/cm². Thus, a dose of the n⁻ drift region of the conventional RB-IGBT has a deficit of approximately 0.1×10¹²/cm² to 1.6×10¹²/cm² from an ideal dose of the n⁻ drift region, which though depends on the design conditions and the breakdown voltage class of the reverse termination structure.

In contrast, in the RB-IGBT of the present invention, due to the second n-type region 35 provided in the n⁻ drift region 1, the dose of n-type impurities of the reverse termination structure 30 is compensated so as to be the ideal dose of the n⁻ drift region. That is, in the reverse termination structure 30, the sum of the dose of the n⁻ drift region 1 and the dose of the second n-type region 35 is the ideal dose of the n⁻ drift region 1. Specifically, when the breakdown voltage is approximately 1200 V to 1700 V, for example, the sum of the dose of the n⁻ semiconductor substrate before being loaded into the manufacturing processes and the dose of oxygen donors occurring in the n⁻ semiconductor substrate due to formation of the p⁺ isolation region 41 is approximately 1.4×10¹²/cm² to 1.6×10¹²/cm². Due to this, the dose of the n⁻ semiconductor substrate is lower than the ideal dose of the n⁻ drift region 1. Thus, the deficit in the dose of the n⁻ semiconductor substrate (=[ideal dose of n⁻ drift region 1]−[dose of n⁻ semiconductor substrate before manufacturing]−[dose of oxygen donors occurring in n⁻ semiconductor substrate due to formation of p⁺ isolation region 41]) may be compensated by the second n-type region 35. Specifically, the dose of the first ion implantation 53 may be approximately 0.1×10¹²/cm² to 1.6×10¹²/cm², for example, which though depends on the forming method of the second n-type region 35, the design conditions and the breakdown voltage class of the reverse termination structure 30.

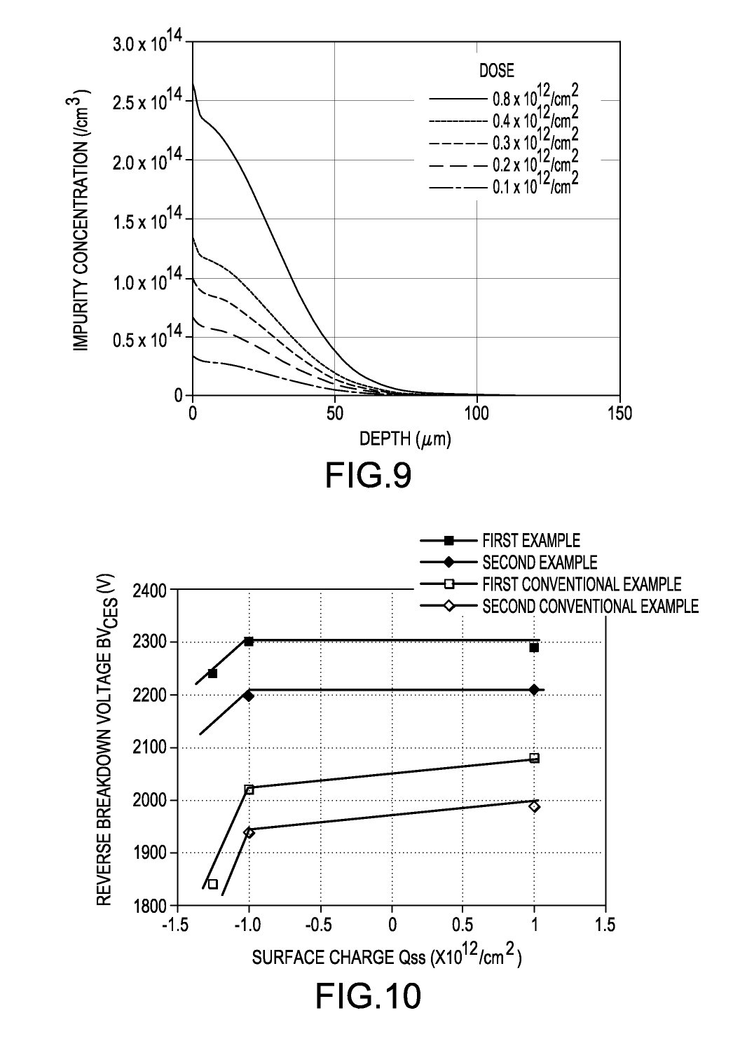

Next, a relation between the dose of the first ion implantation 53 and the dose of the second n-type region 35 was verified. FIG. 9 is a characteristic diagram illustrating an impurity-concentration profile along line A-A′ of FIG. 1. In FIG. 9, a vertical axis represents an n-type impurity concentration of the reverse termination structure 30 and the horizontal axis represents the depth from the interface between the front surface of the substrate and the isolation oxide film 33. The results of simulation of the dose of the second n-type region 35 of the manufactured RB-IGBT when the dose of the first ion implantation 53 for forming the second n-type region 35 according to the first embodiment was changed are illustrated in FIG. 9. FIG. 9 illustrates the n-type impurity-concentration profile of the reverse termination structure 30 for each dose of the first ion implantation 53. The dose of the first ion implantation 53 was changed to 0.1×10¹²/cm², 0.2×10¹²/cm², 0.3×10¹²/cm², 0.4×10¹²/cm², and 0.8×10¹²/cm². As illustrated in FIG. 9, it was confirmed that when the dose of the first ion implantation 53 was set to 0.1×10¹²/cm² or higher, the surface concentration of the second n-type region 35 near the interface between the front surface of the substrate and the isolation oxide film 33 was approximately 10¹⁴/cm² (that is, a dose equal to or higher than the ideal dose of the n⁻ drift region 1 was obtained).

(Reverse Breakdown Voltage)

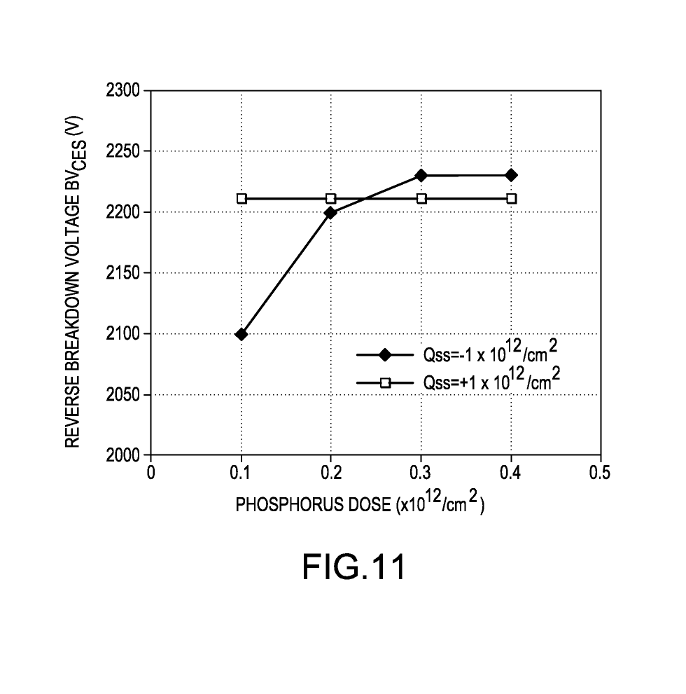

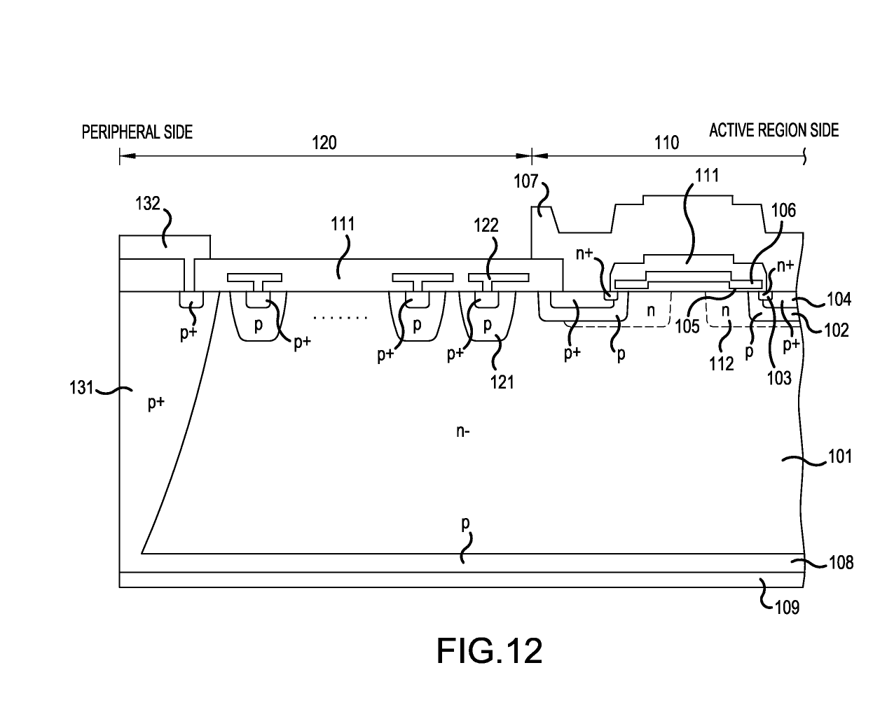

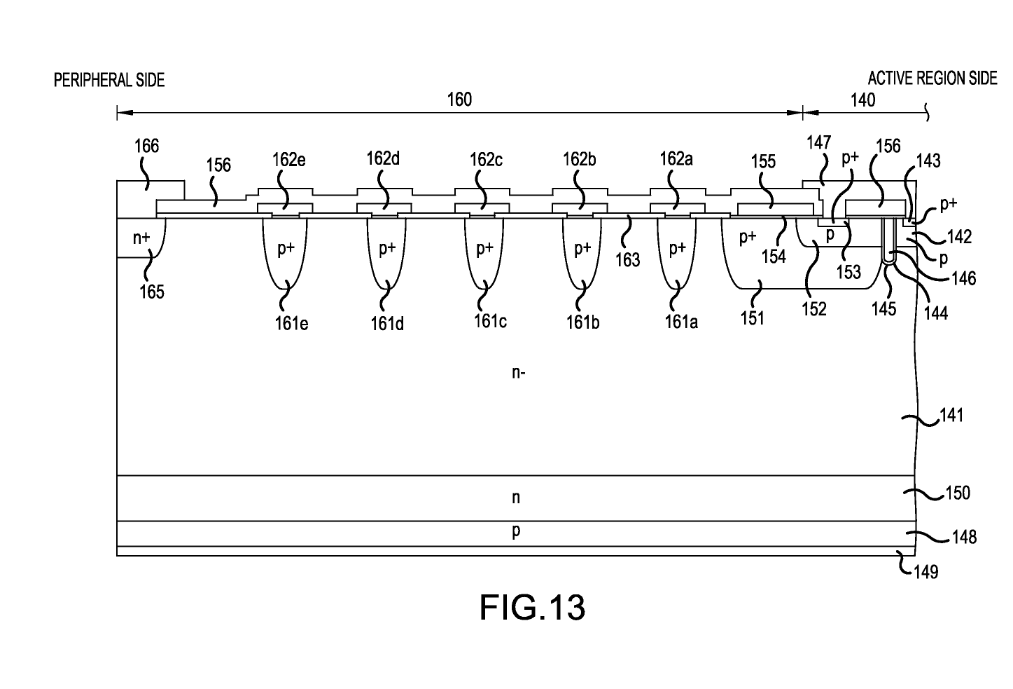

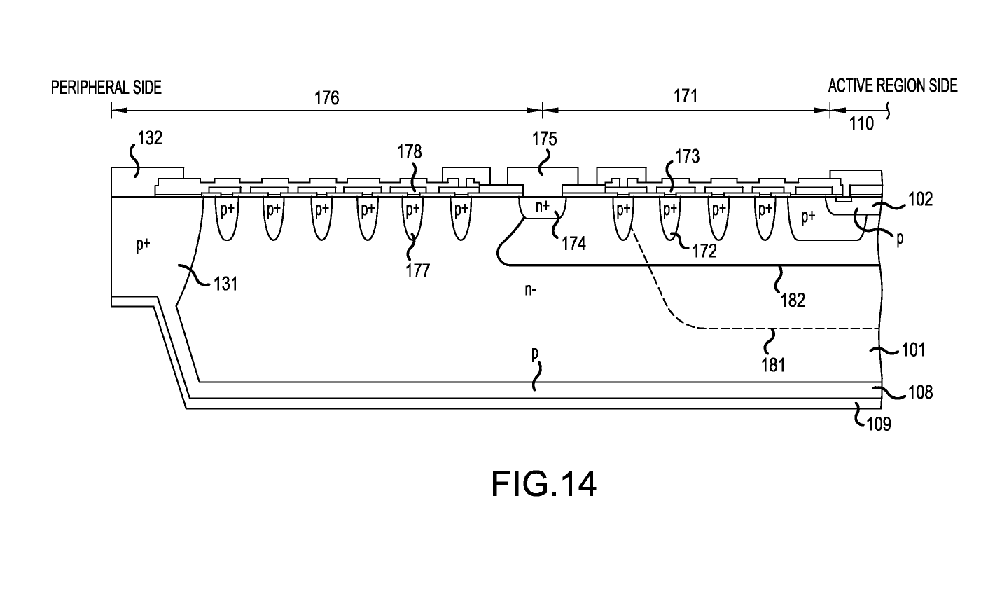

Next, the reverse breakdown voltage of the semiconductor device according to the present invention was verified. FIG. 10 is a characteristic diagram illustrating the relation between the reverse breakdown voltage of the semiconductor device according to first and second examples and the surface charge of the reverse termination structure. FIG. 11 is a characteristic diagram illustrating the relation of the reverse breakdown voltage of the semiconductor device according to the second embodiment and the dose of the second n-type region of the reverse termination structure. First, the results of simulation of the relation between the reverse breakdown voltage of the RB-IGBT having the reverse termination structure 30 including eighteen second FLRs 31 and the surface charge of the reverse termination structure 30 are illustrated in FIG. 10. The first and second examples have the structure conforming to the first embodiment except that the thickness of the n⁻ drift region 1 is different. The thickness of the n⁻ drift region 1 was 275 μm for the first example and 265 μm for the second example.

The resistivity of the n⁻ semiconductor substrate before being loaded into the manufacturing processes was 130 Ω·cm. The dose of the first ion implantation 53 for forming the second n-type region 35 was 0.2×10¹²/cm². Electric charges from the outside were present on the interface between a passivation protection film (not illustrated) and the second metal FP 34 and the interlayer insulating film 7. FIG. 10 illustrates first and second conventional comparative examples which do not have the second n-type region 35. The other configurations of the first and second conventional examples are the same as those of the first and second examples, respectively. From the results illustrated in FIG. 10, it was confirmed for both the first and second examples that even when surface charges (positive charges (Qss>0) and negative charges (Qss<0)) were present, it was possible to improve the breakdown voltage by 200 V or more than the first and second conventional examples.

Next, the results of simulation of the reverse breakdown voltage of the RB-IGBT when the first ion implantation 53 for forming the second n-type region 35 was performed using the semiconductor device of the second example while changing the dose are illustrated in FIG. 11. The number of second FLRs 31 of the reverse termination structure 30 was eighteen. The dose of the first ion implantation 53 was changed in the range of 0.1×10¹²/cm² to 0.4×10¹²/cm². FIG. 11 illustrates a case where positive charges (Qss=+1×10¹²/cm²) are present as surface charges and a case where negative charges (Qss=−1×10¹²/cm²) are present as surface charges. From the results illustrated in FIG. 11, it was confirmed that when the dose of the first ion implantation 53 was 0.1×10¹²/cm² or more, even if surface charges were present, it was possible to realize a breakdown voltage of 2100 V or higher.

### Second Embodiment

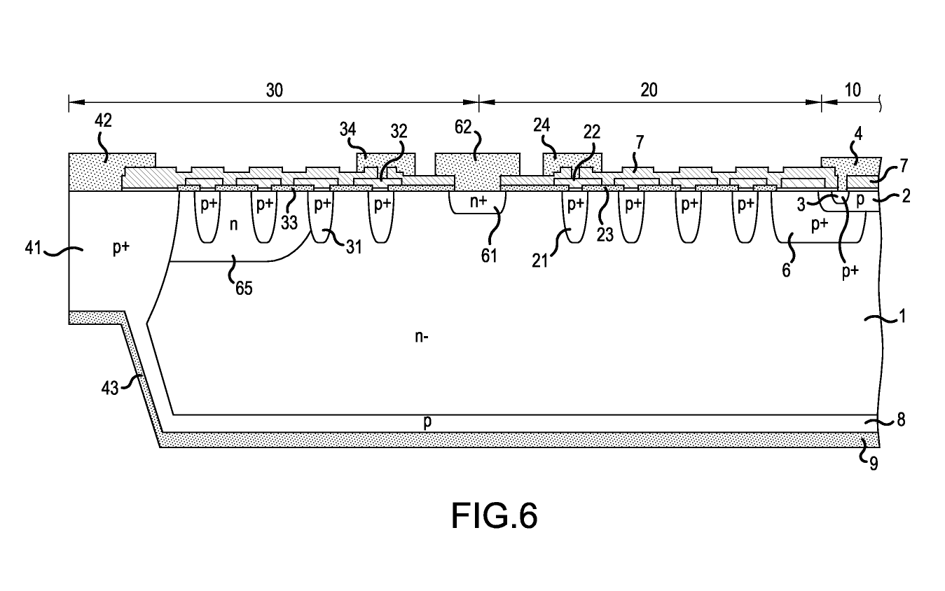

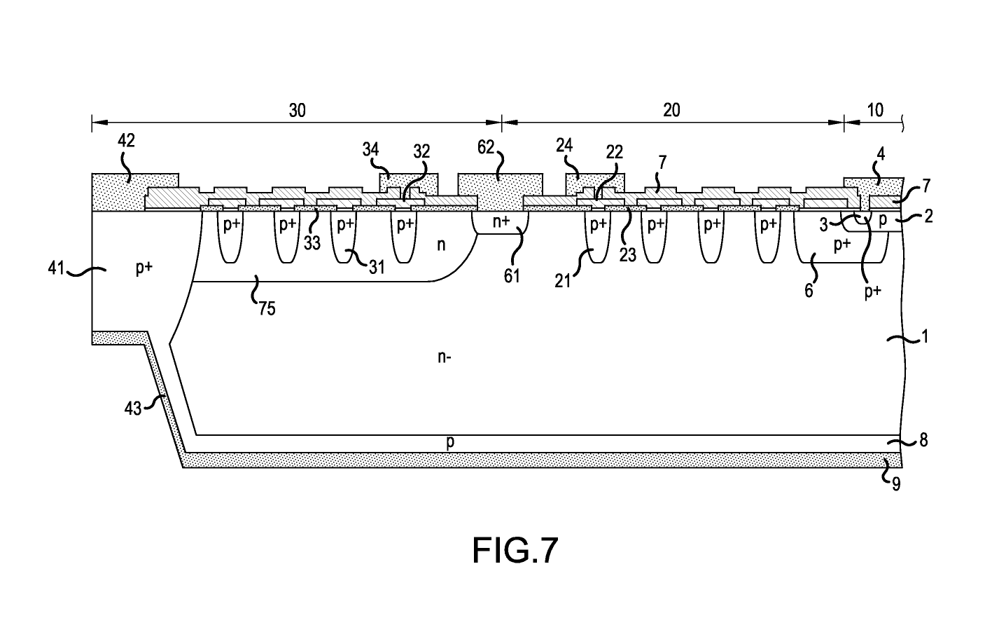

Next, a semiconductor device according to a second embodiment will be described. FIG. 6 is a cross-sectional view illustrating a configuration of the semiconductor device according to the second embodiment. FIG. 7 is a cross-sectional view illustrating another example of the configuration of the semiconductor device according to the second embodiment. The semiconductor device of the second embodiment is different from the semiconductor device of the first embodiment in that a n⁺ channel stopper region 61 and a channel stopper electrode (first metal film) 62 conductively connected to the n⁺ channel stopper region 61 are provided between the forward termination structure 20 and the reverse termination structure 30. Here, in the second embodiment, the first n-type region 5 and the p⁺-type region 6 are selectively provided similarly to the first embodiment, and FIGS. 6 and 7 illustrate a case where the p⁺-type region 6 only is provided.

The n⁺ channel stopper region 61 has a function of stopping a depletion layer that grows from the active region 10 toward the periphery of the substrate and a depletion layer that grows from the periphery of the substrate toward the active region 10. A p⁺ channel stopper region may be provided instead of the n⁺ channel stopper region 61. Moreover, a second n-type region 65 may be provided so as not to be in contact with the n⁺ channel stopper region 61 as illustrated in FIG. 6, and a second n-type region 75 may be provided so as to be in contact with the n⁺ channel stopper region 61 as illustrated in FIG. 7.

In a method of manufacturing the semiconductor device according to the second embodiment, the n⁺ channel stopper region 61 and the channel stopper electrode 62 may be formed when the front surface device structure is formed in the method of manufacturing the semiconductor device according to the first embodiment. Moreover, an opening width of the resist mask 52 used for the first ion implantation 53 for forming the second n-type regions 65 and 75 may be adjusted according to the design conditions of the semiconductor device according to the second embodiment. The other configurations of the method of manufacturing the semiconductor device according to the second embodiment are the same as those of the method of manufacturing the semiconductor device according to the first embodiment.

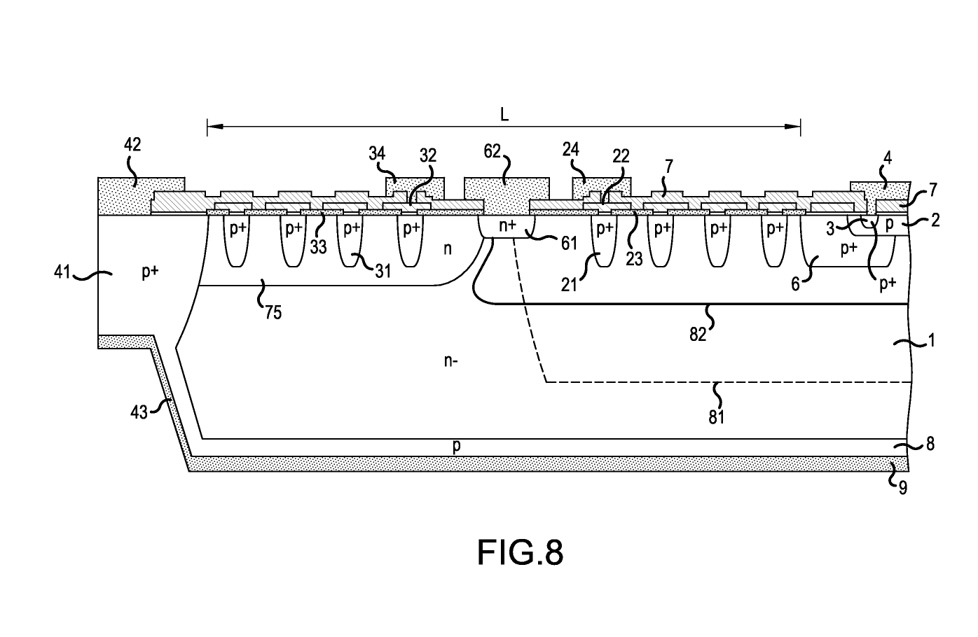

The operation of the termination structure of the semiconductor device according to the respective embodiments will be described with reference to FIG. 8. FIG. 8 is a cross-sectional view illustrating the state of a depletion layer, during application of a maximum voltage, of the semiconductor device according to the present invention. Another example of the semiconductor device according to the second embodiment illustrated in FIG. 7 will be described. As illustrated in FIG. 8, when a maximum forward voltage is applied, due to the first FLR 21 of the forward termination structure 20 and the second metal FP 34 of the reverse termination structure 30, the depletion layer 81 that grows from the pn junction between the p base region 2 and the n⁻ drift region 1 toward the outer side of the substrate stops at the n⁺ channel stopper region 61. That is, a forward breakdown voltage having the magnitude corresponding to the distance between the active region 10 and the n⁺ channel stopper region 61 is maintained.

On the other hand, even when the number of second FLRs 31 of the reverse termination structure 30 is set to be the same as the number of first FLRs 21 of the forward termination structure 20, when a maximum reverse voltage is applied, due to the second FLR 31 and the second n-type region 75 of the reverse termination structure 30 and the first metal FP 24 of the forward termination structure 20, the depletion layer 82 that grows from the pn junction between the p⁺ isolation region 41 and the p collector region 8, and the n⁻ drift region 1 toward the inner side of the substrate stops at the n⁺ channel stopper region 61. That is a reverse breakdown voltage having the magnitude corresponding to the distance between the p⁺ isolation region 41 and the n⁺ channel stopper region 61 is maintained. Moreover, when the n⁺ channel stopper region is not provided as in the case of the first embodiment, the extension length of the ends of the first and second FPs 22 and 32 extended to the isolation oxide films 23 and 33 and the extension length of the ends of the first and second metal FPs 24 and 34 extended to the interlayer insulating film 7 may be adjusted so that the depletion layers 81 and 82 stops at the vicinity of the boundary between the forward termination structure 20 and the reverse termination structure 30.

For example, in the conventional RB-IGBT having the breakdown voltage of 1700 V, the forward termination structure 171 having eighteen first FLRs 172 and the reverse termination structure 176 having twenty-four second FLRs 177 are provided. In contrast, in the RB-IGBT of the present embodiment, the number of at least second FLRs 31 can be decreased by six and the number of first and second FLRs 21 and 31 both can be set to eighteen. Due to this, the width L of the termination structure of the RB-IGBT according to the present embodiment (L=[width of forward termination structure 20]+[width of reverse termination structure 30]) can be reduced by approximately 200 μm as compared to the conventional RB-IGBT. Specifically, the width (1430 μm) of the termination structure of the conventional RB-IGBT can be reduced to 1230 μm.

As described above, according to the respective embodiments, since the second n-type region is provided on the front surface side of the substrate of the reverse termination structure, the dose of the n⁻ drift region of the reverse termination structure is compensated, and the reverse breakdown voltage and the charge resistance properties during application of the reverse voltage can be improved as compared to the conventional structure. Due to this, a growth width of a depletion layer which grows toward the inner side of the substrate within the reverse termination structure during application of the maximum reverse voltage can be set to be identical to a growth width of a depletion layer which grows toward the outer side of the substrate within the forward termination structure during application of the maximum forward voltage. Thus, it is possible to reduce the number of second FLRs of the reverse termination structure as compared to the conventional structure.

Moreover, according to the respective embodiments, since the number of second FLRs of the reverse termination structure can be reduced as compared to the conventional structure, when the chip size is the same as the conventional structure, it is possible to increase the area of the active region and to reduce the ON voltage as compared to the conventional structure. Due to this, the conduction loss is reduced and the efficiency can be improved. Further, according to the respective embodiments, since the number of second FLRs of the reverse termination structure can be reduced as compared to the conventional structure, it is possible to reduce the chip size as compared to the conventional structure. When the chip size is reduced as compared to the conventional structure, it is possible to reduce the device cost. Due to this, it is possible to reduce the cost of various energy apparatuses which use RB-IGBTs and to accelerate application of RB-IGBTs to various energy apparatuses.

The present invention is not limited to the embodiments described above, but various changes can be made without departing from the spirit of the present invention. For example, the dimensions of respective portions, breakdown voltages, the number of field limited rings, and the like can be set in various ways according to the required specifications or the like. Moreover, in the embodiments, although a case where a planar gate-type front surface device structure has been described by way of an example, a trench gate-type front surface device structure may be provided instead of the planar gate-type front surface device structure. Further, in the present embodiment, the n type and the p type may be reversed.

As described above, the semiconductor device and the method of manufacturing the semiconductor device according to the present invention are useful in power semiconductor devices which are used for matrix converters, uninterruptible power supplies (UPS), energy converters, and the like which use RB-IGBTs.

What is claimed is:

1. A semiconductor device comprising:
a second conductivity-type isolation region provided on a side surface of a first conductivity-type semiconductor substrate so as to extend from a front surface of the first conductivity-type semiconductor substrate to reach a back surface of the first conductivity-type semiconductor substrate;
a first edge termination region provided between an active region and the second conductivity-type isolation region so as to surround the active region;
a second edge termination region provided between the first edge termination region and the second conductivity-type isolation region so as to surround the first edge termination region;
a plurality of second conductivity-type semiconductor regions selectively provided in a surface layer of the front surface of the first conductivity-type semiconductor substrate in the first and second edge termination regions;
a conductive film being in contact with the second conductivity-type semiconductor region; and
a first conductivity-type semiconductor region provided in the surface layer of the front surface of the first conductivity-type semiconductor substrate in the second edge termination region so as to be in contact with second conductivity-type isolation region and also be in contact with
at least one second conductivity-type semiconductor region, with the first conductivity-type semiconductor region exhibiting lower resistivity than the first conductivity-type semiconductor substrate.

2. The semiconductor device according to claim 1, wherein
the first conductivity-type semiconductor region includes at least the one second conductivity-type semiconductor region.

3. The semiconductor device according to claim 1, further comprising:
a channel stopper region provided in the surface layer of the front surface of the first conductivity-type semiconductor substrate at a boundary between the first edge termination region and the second edge termination region so as to stop a depletion layer which expands from the side of the active region during application of a forward voltage; and
a first metal film being in contact with the channel stopper region.

4. The semiconductor device according to claim 1, further comprising:
a channel stopper region provided in the surface layer of the front surface of the first conductivity-type semiconductor substrate at a boundary between the first edge termination region and the second edge termination region so as to stop a depletion layer which expands from the side of the second conductivity-type isolation region during application of a reverse voltage; and
a first metal film being in contact with the channel stopper region.

5. The semiconductor device according to claim 1, wherein
a dose of the first conductivity-type semiconductor region is 0.1×10¹²/cm² to 1.6×10¹²/cm².

6. The semiconductor device according to claim 1, further comprising:
an oxide film provided on a front surface of a portion of the first conductivity-type semiconductor substrate, with the portion being sandwiched between adjacent second conductivity-type semiconductor regions, wherein
the conductive film is extended over the oxide film.

7. The semiconductor device according to claim 6, wherein
in the first edge termination region, an extension length of the conductive film over the oxide film at the active region side end is larger than the one at the isolation region side end.

8. The semiconductor device according to claim 6, wherein
in the second edge termination region, an extension length of the conductive film over the oxide film at the active region side end is smaller than the one at the isolation region side end.

9. The semiconductor device according to a claim 1, further comprising:
a second metal film that is in contact with the conductive film closest to the second edge termination region among the plurality of conductive films of the first edge termination region; and
an interlayer insulating film that covers the conductive film, wherein
the second metal film is extended over the interlayer insulating film, and
an isolation region side end of the second metal film is closer to the isolation region than an isolation region side end of the conductive film to which the second metal film is connected.

10. The semiconductor device according to claim 9, further comprising:
a third metal film that is in contact with the conductive film closest to the first edge termination region among the plurality of conductive films of the second edge termination region, wherein
the third metal film is extended over the interlayer insulating film, and
an active region side end of the third metal film is closer to the active region than an active region side end of the conductive film to which the third metal film is connected.

11. A method of manufacturing a semiconductor device including:
a second conductivity-type isolation region provided on a side surface of a first conductivity-type semiconductor substrate;
a first edge termination region provided between an active region and the second conductivity-type isolation region so as to surround the active region; and
a second edge termination region provided between the first edge termination region and the second conductivity-type isolation region so as to surround the first edge termination region, the method comprising:
a first ion implantation step of selectively implanting first conductivity-type impurities to a front surface of the first conductivity-type semiconductor substrate in the second edge termination region;
a second ion implantation step of selectively implanting second conductivity-type impurities to a front surface on a periphery of the first conductivity-type semiconductor substrate after the first ion implantation step is performed;
a first thermal diffusion step of diffusing the first conductivity-type impurities to form a first conductivity-type semiconductor region having lower resistivity than the first conductivity-type semiconductor substrate so as to be in contact with the second conductivity-type isolation region on a surface layer of the front surface of the first conductivity-type semiconductor substrate;
a second thermal diffusion step of diffusing the second conductivity-type impurities to form the second conductivity-type isolation region so as to be in contact with the first conductivity-type semiconductor region on the periphery of the first conductivity-type semiconductor substrate, with the second conductivity-type isolation region extending from the front surface of the first conductivity-type semiconductor substrate to reach a back surface of the first conductivity-type semiconductor substrate; and
a forming step of forming a plurality of second conductivity-type semiconductor regions, at least a portion of which is in contact with the first conductivity-type semiconductor region on the surface layer of the front surface of the first conductivity-type semiconductor substrate in the second edge termination region after the second diffusion step is performed.

12. The method of manufacturing a semiconductor device according to claim 11, wherein
the first diffusion step is performed before the second ion implantation step is performed, or is performed simultaneously with the second diffusion step after the second ion implantation step is performed.
